(19) United States
(12) Patent Application Publication
(10) Pub. No.: US 2026/0186595 A1
(43) Pub. Date: Jul. 2, 2026

(54) DISPLAY DEVICE

(71) Applicant: LG Display Co., Ltd., Seoul (KR)

(72) Inventors: Jinyong JANG, Daegu (KR); Sangug AN, Gumi-si (KR); KyungSu HA, Gumi-si (KR)

(73) Assignee: LG Display Co., Ltd., Seoul (KR)

(21) Appl. No.: 19/435,279

(22) Filed: Dec. 29, 2025

(30) Foreign Application Priority Data
Dec. 30, 2024 (KR) 10-2024-0201092

(51) Int. Cl. G06F 3/041; H10K 59/40; H10K 59/80; G06F 3/044

(52) U.S. Cl. CPC G06F 3/0412; H10K 59/40; H10K 59/8792; G06F 3/04164; G06F 3/0446; G06F 2203/04111

(57) ABSTRACT

A display device includes a substrate having a plurality of sub-pixels, a light-emitting element disposed in each sub-pixel of the plurality of sub-pixels, an encapsulation layer disposed on the light-emitting element, and a touch unit disposed on the encapsulation layer. The touch unit includes a plurality of bridge metals disposed on the encapsulation layer, a black matrix disposed on the bridge metals with openings corresponding to the sub-pixels, and a plurality of sensor metals disposed on the black matrix. The touch unit further includes a plurality of bridge variable regions disposed between the bridge metals and a plurality of sensor variable regions disposed between the sensor metals. The bridge variable regions are positioned so as to overlap the black matrix and the sensor metals, allowing selective routing of the bridge metals while reducing visibility of metal patterns.

### CROSS-REFERENCE TO RELATED APPLICATIONS

This application claims the priority of Korean Patent Application No. 10-2024-0201092 filed on December 30, 2024, in the Korean Intellectual Property Office, the disclosure of which is incorporated herein by reference.

### BACKGROUND

### Technical Field

The present disclosure relates to a display device, and more particularly, to a display device in which a touch unit is embedded.

### DESCRIPTION OF THE RELATED ART

An electroluminescent display device is a self-emitting display device and does not require a separate light source unlike a liquid crystal display device, and thus may be manufactured as a lightweight and thin display device. In addition, the electroluminescent display device is advantageous not only in terms of power consumption due to low voltage driving, but also in terms of color implementation, response speed, viewing angle, and contrast ratio (CR), so it is being studied as a next-generation display.

Among the electroluminescent display devices, there is a touch screen integrated display device including a touch unit capable of recognizing a user’s touch. Since the touch screen integrated display device can directly input information using a finger or a pen, it is widely applied to navigation, portable terminals, and home appliances.

### BRIEF SUMMARY

The present disclosure focuses on achieving a display in which touch electrode patterns are not visually recognizable. Most routing flexibility is implemented through bridge variable regions that are positioned beneath both the black matrix and the sensor metal, which prevents selectively added bridge metal from being seen. In contrast, the design reduces the number of sensor variable regions and arranges them in a paired configuration with an adjacent compensation metal. This pairing ensures that the presence or absence of sensor metal does not result in a noticeable pattern difference, addressing a common visibility issue in touch on encapsulation displays.

The present disclosure also provides a routing system that allows various electrical connection schemes. Optional metal may be formed in selected sensor variable regions and bridge variable regions, enabling many possible interconnections between sensor lines, bridge metals, and sub pixel rows or columns. This arrangement supports dual feeding and multi feeding touch configurations used in large display panels while maintaining a uniform external appearance, since routing changes do not create visible nonuniformities.

In addition, the present disclosure incorporates a half cylindrical lens array above the sensor metal to limit viewing angles in the vertical direction while maintaining a wide viewing angle horizontally. The lens array is integrated into the touch stack in a manner that does not expose underlying metal routing. As a result, the present disclosure provides a display panel that combines routing flexibility, stable electrical characteristics, and a clean visual appearance.

Various embodiments of the present disclosure provide a display device in which a touch unit is embedded.

Various embodiments of the present disclosure provide a display device in which a touch unit including a variable region in which a metal is selectively disposed is embedded.

Various embodiments of the present disclosure provide a display device in which a metal of a touch unit is not visible.

Various embodiments of the present disclosure provide a display device in which most of a plurality of variable regions are formed under a black matrix and a sensor metal to minimize visibility of a touch electrode due to a metal difference in the variable region.

Various embodiments of the present disclosure provide a display device which forms a metal in a sensor variable region to form various connection structures of a sensor metal.

Various embodiments of the present disclosure provide a display device which forms a metal in a bridge variable region to form various connection structures of the bridge metal.

Technical benefits of the present disclosure are not limited to the above-mentioned benefits, and other benefits, which are not mentioned above, can be clearly understood by those skilled in the art from the following descriptions.

According to an aspect of the present disclosure, a display device includes a substrate including a plurality of sub-pixels, a light-emitting element disposed in each of the plurality of sub-pixels; an encapsulation layer disposed on the light-emitting element, and a touch unit disposed on the encapsulation layer. The touch unit includes a plurality of bridge metals disposed on the encapsulation layer, a black matrix disposed on the plurality of bridge metals and having a plurality of openings overlapping the plurality of sub-pixels, a plurality of sensor metals disposed on the black matrix, a plurality of bridge variable regions disposed between the plurality of bridge metals, and a plurality of sensor variable regions disposed between the plurality of sensor metals. The plurality of bridge variable regions overlap the black matrix and the plurality of sensor metals. Accordingly, the plurality of bridge variable regions in which metal is selectively disposed may be shielded by the black matrix and the sensor metal, so that a pattern of the touch electrode caused by the bridge variable regions is not visually recognized.

Other detailed matters of the embodiments are included in the detailed description and the drawings.

According to the present disclosure, it is possible to provide a display device in which a touch unit is embedded.

According to the present disclosure, it is possible to provide a display device in which a touch unit including a variable region in which a metal is selectively disposed is embedded.

According to the present disclosure, it is possible to prevent the metal of the touch unit from being visually recognized.

According to the present disclosure, most of a plurality of variable regions are formed between the bridge metals to shield the variable regions with the black matrix and the sensor metal.

According to the present disclosure, the black matrix and the sensor metal shield the plurality of bridge variable regions to minimize the visibility of the touch electrode due to the metal difference of the plurality of bridge variable regions.

According to the present disclosure, a second sensor variable region is formed between a plurality of first sensor metals to compensate for a shape difference due to the presence or absence of metal in the first sensor variable region.

According to the present disclosure, various connection structures of the sensor metal may be formed by forming a metal in the sensor variable region.

According to the present disclosure, various connection structures of the bridge metal may be formed by forming a metal in the bridge variable region.

The effects according to the present disclosure are not limited to the contents exemplified above, and more various effects are included in the present disclosure.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1A is a schematic configuration diagram of a display device according to an exemplary embodiment of the present disclosure;

FIG. 1B is a view illustrating an example of using a display device according to an exemplary embodiment of the present disclosure;

FIG. 1C is an exemplary plan view of a display device according to an exemplary embodiment of the present disclosure;

FIGS. 2 and 3 are schematic plan views of a touch unit of a display device according to an exemplary embodiment of the present disclosure;

FIG. 4 is an enlarged plan view of a display device according to an exemplary embodiment of the present disclosure;

FIG. 5 is a cross-sectional view taken along line A-Aʹ in FIG. 4;

FIG. 6 is an enlarged plan view of an area X of FIG. 4;

FIGS. 7A and 7B are cross-sectional views taken along line B-B′ of FIG. 6’ and

FIG. 8 is an enlarged plan view of a display device according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure. Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only.” Any references to singular may include plural unless expressly stated otherwise.

Components are interpreted to include an ordinary error range even if not expressly stated.

When the position relation between two parts is described using the terms such as “on,” “above,” “below,” and “next,” one or more parts may be positioned between the two parts unless the terms are used with the term “immediately” or “directly.”

When an element or layer is disposed “on” another element or layer, another layer or another element may be interposed directly on the other element or therebetween.

Although the terms “first,” “second,” and the like are used for describing various components, these components are not confined by these terms. These terms are merely used for distinguishing one component from the other components. Therefore, a first component to be mentioned below may be a second component in a technical concept of the present disclosure.

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The terms "coupled" and "in contact" should be interpreted in the same manner.

The features of various embodiments of the present disclosure can be partially or entirely adhered to or combined with each other and can be interlocked and operated in technically various ways, and the embodiments can be carried out independently of or in association with each other.

Hereinafter, exemplary embodiments of the present disclosure will be described in detail with reference to accompanying drawings.

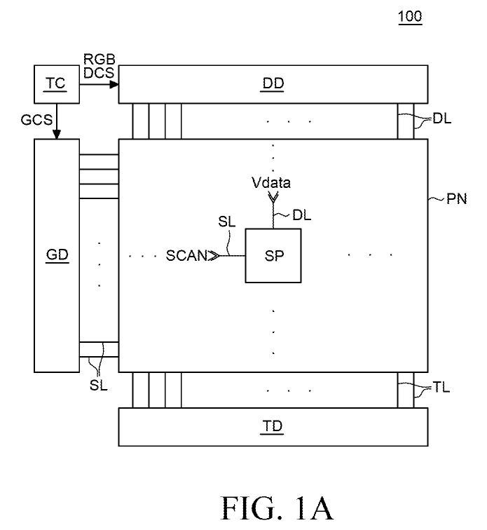

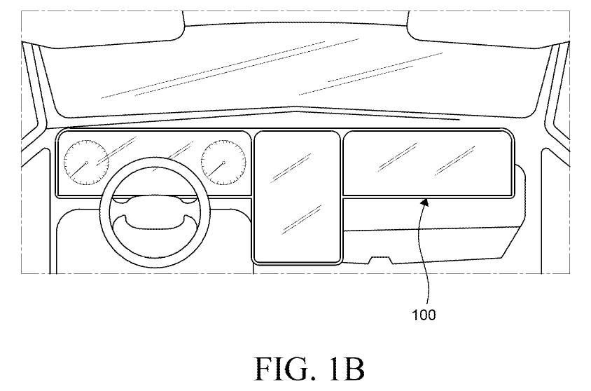

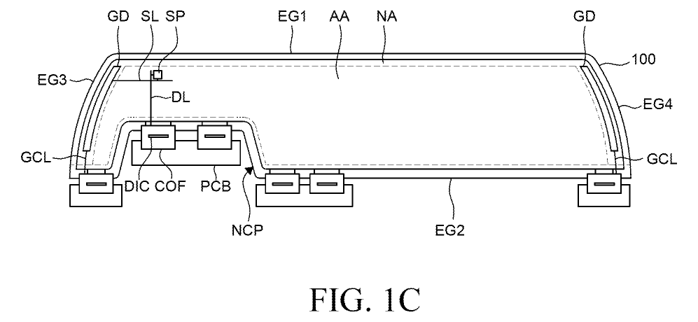

FIG. 1A is a schematic configuration diagram of a display device according to an exemplary embodiment of the present disclosure. FIG. 1B is a view illustrating an example of using a display device according to an exemplary embodiment of the present disclosure. FIG. 1C is an exemplary plan view of a display device according to an exemplary embodiment of the present disclosure. In FIG. 1A, for the convenience of description, among various components of the display device 100, only a display panel PN, a gate driver GD, a data driver DD, a touch driver TD, and a timing controller TC are illustrated.

Referring to FIG. 1A, a display device 100 includes a display panel PN including a plurality of sub-pixels SP, a gate driver GD and a data driver DD which supply various signals to the display panel PN, a timing controller TC which controls the gate driver GD and the data driver DD, and a touch driver TD which senses a touch input.

The display panel PN is configured to display images to a user and includes a plurality of sub-pixels SP. In the display panel PN, the plurality of scan lines SL and the plurality of data lines DL intersect each other, and each of the plurality of sub-pixels SP is connected to the scan line SL and the data line DL. In addition, although not illustrated in the drawings, each of the plurality of sub-pixels SP may be connected to a high potential power line, a low potential power line, a reference line, and the like.

The plurality of sub-pixels SP is a minimum unit constituting a screen, and each of the plurality of sub-pixels SP includes a light-emitting element and a pixel circuit for driving the light-emitting element. The plurality of light-emitting elements may be differently defined depending on the type of the display device 100. For example, when the display device 100 is an organic light emitting display device 100, the light-emitting element may be an organic light-emitting element (OLED).

The gate driver GD supplies a plurality of scan signals SCAN to a plurality of scan lines SL according to a plurality of gate control signals GCS provided from the timing controller TC. FIG. 1 illustrates that one gate driver GD is disposed to be spaced apart from one side of the display panel PN. However, the number and arrangement of the gate drivers GD are not limited thereto.

The data driver DD converts image data RGB transmitted from the timing controller TC into a data voltage Vdata using a reference gamma voltage according to a plurality of data control signals DCS provided from the timing controller TC. The data driver DD may supply the converted data voltage Vdata to the plurality of data lines DL.

The timing controller TC aligns image data RGB input from the outside and supplies the image data RGB to the data driver DD. The timing controller TC may generate a gate control signal GCS and a data control signal DCS by using a synchronization signal input from the outside, for example, a dot clock signal, a data enable signal, and a horizontal/vertical synchronization signal. Further, the timing controller TC supplies the generated gate control signal GCS and data control signal DCS to the gate driver GD and the data driver DD, respectively, to control the gate driver GD and the data driver DD.

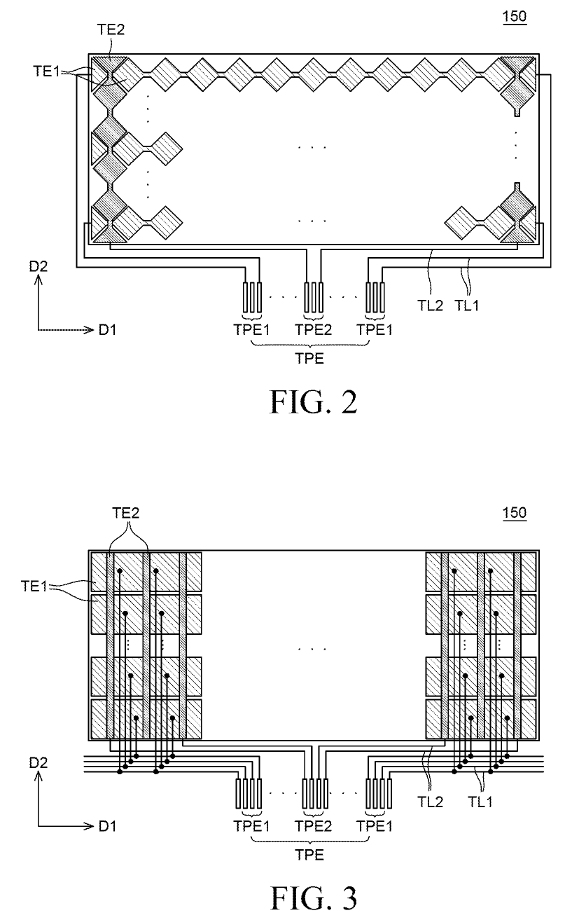

The touch driver TD drives the touch unit 150 (see FIG. 2) during a touch sensing period based on a touch enable signal input from the timing controller TC or an external component. The touch driver TD may sense a touch input based on a signal from the touch unit 150.

Referring to FIGS. 1B and 1C together, the display device 100 is not limited to a TV, a monitor, or a mobile phone and may be used in various fields. For example, the display device 100 may be used for a dashboard of a vehicle. The display device 100 of the dashboard may be disposed in front of the vehicle. For example, the display device 100 of the dashboard may be disposed in at least one of the driver’s seat and the front passenger seat, or may be disposed to extend from the driver’s seat to the front passenger seat.

The display device 100 of the vehicle may serve as an input unit for displaying various information related to the vehicle or manipulating various functions of the vehicle. Specifically, the display device 100 may display an interface for operating an air conditioner, an audio system, a navigation system, or the like of a vehicle, or display information such as a speed, a fuel amount, and a driving distance of the vehicle.

Referring to FIG. 1C, the display device 100 may have a general rectangular shape, but may have various shapes depending on a product to which the display device 100 is to be applied. For example, when the display device 100 is applied to the vehicle, the display device 100 may have a heterogeneous shape having curved surfaces and a notch portion NCP as illustrated in FIG. 1C.

Specifically, the display device 100 may include an upper first edge EG1 extending in a straight line, a lower second edge EG2 having a notch portion NCP, a left third edge EG3 formed of a curved surface, and a right fourth edge EG4 formed of a curved surface.

In the notch portion NCP, a portion of the display device 100 may be notched and formed to be concave.

The display area AA may also include edges corresponding to the edges EG1, EG2, EG3 and EG4 of the display device 100. The display area AA may include a concave portion corresponding to the notch portion NCP, a convex side portion corresponding to the curved third edge EG3 and the fourth edge EG4, and the like.

The plurality of flexible films COF each including the driving IC DIC may be connected to the second edge EG2 of the display device 100. The flexible film COF may be a film in which various components are disposed on a base film having flexibility. For example, a driving IC DIC, which is a component that includes a data driver DD and processes data for displaying images and a driving signal, may be disposed on the flexible film COF. Some of the plurality of flexible films COF may be connected to a part of the second edge EG2 corresponding to the notch portion NCP, and the rest may be connected to the rest of the second edge EG2 excluding the notch portion NCP.

The printed circuit board PCB may be electrically connected to one or more flexible films COF and supply signals to the driving IC DIC. The printed circuit board PCB may be electrically connected to the flexible film COF. Various components for supplying various signals to the driving IC DIC may be disposed on the printed circuit board PCB. For example, various components such as a timing controller TC, a power management integrated circuit (PMIC), a memory, or a processor may be disposed on the printed circuit board (PCB).

The gate driver GD is disposed in the non-display area NA on both sides of the display area AA, that is, the non-display area NA on the third edge EG3 and the fourth edge EG4. The gate driver GD may be driven by receiving a signal from the flexible film COF through the gate driving line GCL. The gate driver GD may be disposed along the curved third edge EG3 and the fourth edge EG4 and may be disposed in a heterogeneous region.

The low potential power line is disposed in the non-display area NA. The low potential power line may receive a signal from the flexible film COF. The low potential power line is disposed to surround the display area AA and may transmit a low potential power voltage to the display area AA. The low potential power line may be disposed along the edges EG1, EG2, EG3, and EG4 of the display device 100 and may have a shape corresponding to the edges EG1, EG2, EG3, and EG4 of the display device 100.

Accordingly, the display device 100 is applied to various products and may be formed in a heterogeneous shape, and configurations such as the gate driver GD, the flexible film COF, and the low potential power line may be disposed to correspond to the heterogeneous shape.

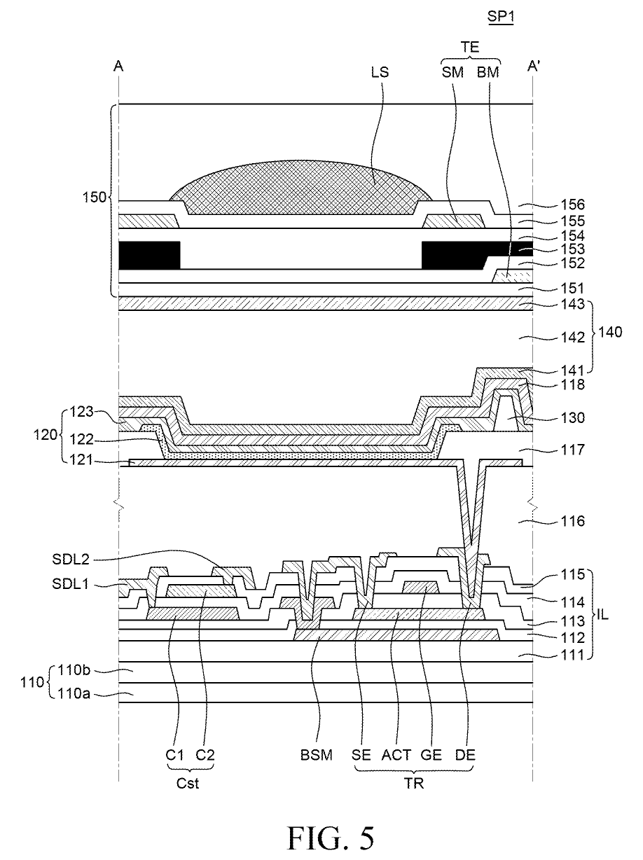

Meanwhile, the display panel PN of the display device 100 according to the exemplary embodiment of the present disclosure may have a Touch On Encap (TOE) structure in which the touch unit 150 is directly formed on the encapsulation layer 140 (see FIG. 5). The display panel PN may include the touch unit 150 to sense a touch input.

The touch unit 150 may have various structures according to a touch sensing method and a signal input method. Hereinafter, the configuration of the touch unit 150 will be described first with reference to FIGS. 2 and 3.

FIGS. 2 and 3 are schematic plan views of a touch unit of a display device according to an exemplary embodiment of the present disclosure. Specifically, FIG. 2 is a schematic plan view of a touch unit 150 having a dual feeding structure, and FIG. 3 is a schematic plan view of a touch unit 150 having a multi-feeding structure.

Touch unit 150 may sense a touch input in a mutual-capacitance method or a self-capacitance method. The mutual capacitance method senses a touch input based on a change in capacitance between the touch driving electrode and the touch sensing electrode. The self-capacitance method senses a touch input based on a change in capacitance between an external input and a touch electrode.

Hereinafter, the description will be made on the assumption that the touch unit 150 of the display device 100 according to the exemplary embodiment of the present disclosure is the touch unit 150 that may be used by integrating a mutual-capacitance method and a self-capacitance method.

Referring to FIGS. 2 and 3, the touch unit 150 includes a plurality of touch lines TL and a plurality of touch electrodes TE. The plurality of touch lines TL includes a plurality of first touch lines TL1 and a plurality of second touch lines TL2, and the plurality of touch electrodes TE includes a plurality of first touch electrodes TE1 and a plurality of second touch electrodes TE2. In this case, as illustrated in FIGS. 2 and 3, the shape and arrangement of the plurality of touch electrodes TE of the touch unit 150 and the connection structure of the touch electrode TE and the touch line TL may be configured in various ways.

For example, referring to FIG. 2, the plurality of first touch electrodes TE1 may be arranged in a matrix form at regular intervals. The plurality of first touch electrodes TE1 may have a rhombic shape. Further, first touch electrodes TE1 on the same line arranged along the first direction D1 among the plurality of first touch electrodes TE1 may be connected to each other. For example, the first touch electrodes TE1 in the n-th row may be electrically connected to each other to form one line of first touch electrode TE1.

The plurality of second touch electrodes TE2 may be arranged in a matrix form at regular intervals. The plurality of second touch electrodes TE2 may have a rhombic shape. The plurality of second touch electrodes TE2 may be alternately disposed with the plurality of first touch electrodes TE1. The second touch electrodes TE2 of the same line arranged in the second direction D2 among the plurality of second touch electrodes TE2 may be connected. For example, the second touch electrodes TE2 in the n-th column may be electrically connected to each other to form one line of second touch electrode TE2. Accordingly, the line of the first touch electrode TE1 and the line of the second touch electrode TE2 may cross each other.

The plurality of first touch lines TL1 is electrically connected to the plurality of first touch electrodes TE1. The plurality of first touch lines TL1 may be electrically connected to the first touch pad electrode TPE1 among the plurality of touch pad electrodes TPE and transmit a touch signal from the first touch pad electrode TPE1 to the plurality of first touch electrodes TE1. For example, the first touch line TL1 may be connected to both ends of one of first touch electrode TE1 composed of a plurality of first touch electrodes TE1 disposed in the same row. Signal delay may be minimized by supplying touch signals to both ends of the line of the first touch electrode TE1.

The plurality of second touch lines TL2 is electrically connected to the plurality of second touch electrodes TE2. The plurality of second touch lines TL2 may be electrically connected to the second touch pad electrode TPE2 among the plurality of touch pad electrodes TPE and may electrically connect the second touch pad electrode TPE2 and the plurality of second touch electrodes TE2. For example, the second touch line TL2 may be connected to one end of a line of the second touch electrode TE2 composed of a plurality of second touch electrodes TE2 disposed in the same column.

The touch unit 150 of FIG. 2 may have a dual-feeding structure in which signals are simultaneously applied to both ends of the line of the touch electrode TE. For example, as the size of the display device 100 increases, the length of the line of the touch electrode TE made of the same line of touch electrodes TE increases, and signal transmission may be delayed according to the position of the touch electrode TE. Therefore, in order to reduce the transmission/reception time deviation of the touch signal, one or more touch lines TL are connected to the same line constituting the line of the touch electrode TE to minimize the signal delay.

Next, referring to FIG. 3, the plurality of first touch electrodes TE1 may be arranged in a matrix form at regular intervals. The plurality of first touch electrodes TE1 may have a rectangular shape. The first touch electrodes TE1 on the same line arranged along the first direction D1 among the plurality of first touch electrodes TE1 may be simultaneously applied with a signal. For example, a plurality of first touch pad electrodes TPE1 is disposed in the non-display area NA, and an n-th first touch line TL1 electrically connected to an n-th first touch pad electrode TPE1 among the plurality of first touch pad electrodes TPE1 may be connected to a plurality of first touch electrodes TE1 disposed on the same line.

The plurality of second touch electrodes TE2 may be disposed between the plurality of first touch electrodes TE1. The plurality of second touch electrodes TE2 may have a rectangular shape. For example, the plurality of first touch electrodes TE1 and the plurality of second touch electrodes TE2 may be alternately disposed in the first direction D1. The first touch electrode TE1 and the second touch electrode TE2 may be disposed in the same row, and the first touch electrode TE1 and the second touch electrode TE2 may be disposed in different columns. The second touch electrodes TE2 on the same line arranged in the second direction D2 among the plurality of second touch electrodes TE2 may be simultaneously applied with a signal. For example, a plurality of second touch pad electrodes TPE2 disposed in the non-display area NA is disposed, and an n-th second touch line TL2 electrically connected to an n-th second touch pad electrode TPE2 among the plurality of second touch pad electrodes TPE2 may be connected to a plurality of second touch electrodes TE2 disposed on the same line.

The plurality of first touch lines TL1 is electrically connected to the plurality of first touch electrodes TE1. The plurality of first touch lines TL1 may be electrically connected to the first touch pad electrode TPE1 among the plurality of touch pad electrodes TPE and transmit a touch signal from the first touch pad electrode TPE1 to the plurality of first touch electrodes TE1.

The plurality of second touch lines TL2 is electrically connected to the plurality of second touch electrodes TE2. The plurality of second touch lines TL2 may be electrically connected to the second touch pad electrode TPE2 among the plurality of touch pad electrodes TPE and may electrically connect the second touch pad electrode TPE2 and the plurality of second touch electrodes TE2.

Meanwhile, the touch unit 150 of FIG. 3 may have a multi-feeding structure in which signals are simultaneously applied to the plurality of touch electrodes TE. For example, as the size of the display device 100 increases, the length of the line of the touch electrode TE made of the same line of touch electrodes TE increases, and signal transmission may be delayed according to the position of the touch electrode TE. Accordingly, in order to reduce the transmission/reception time deviation of the touch signal, the touch line TL may be connected to each of the plurality of touch electrodes TE of the same line constituting the line of the touch electrode TE to simultaneously apply a signal. Accordingly, the plurality of touch lines TL is connected to each of the plurality of touch electrodes TE one-to-one to reduce the delay of the touch signal and improve the touch performance for the entire area of the display device 100.

Further, the plurality of first touch electrodes TE1 may be touch driving electrodes, and the plurality of second touch electrodes TE2 may be touch sensing electrodes. Further, the plurality of first touch lines TL1 may be touch driving lines, and the plurality of second touch lines TL2 may be touch sensing lines. In this case, the touch driver TD may transmit a touch driving signal to the first touch electrode TE1 through the first touch line TL1, and receive a touch sensing signal from the second touch electrode TE2 through the second touch line TL2.

However, each of the first touch electrode TE1 and the first touch line TL1 may be a touch sensing electrode and a touch sensing line, and each of the second touch electrode TE2 and the second touch line TL2 may be a touch driving electrode and a touch driving line, but the exemplary embodiments of the present disclosure are not limited thereto.

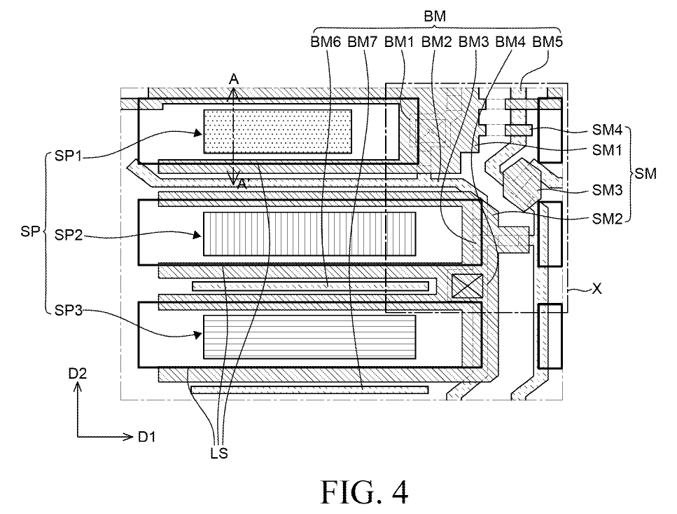

Hereinafter, a detailed structure of the sub-pixel SP and the touch unit 150 of the display panel PN will be described with reference to FIGS. 4 to 8.

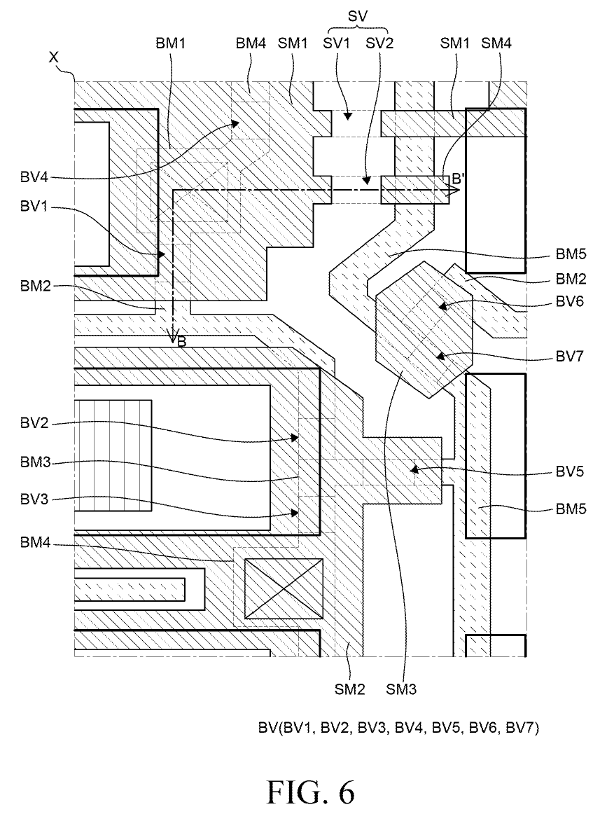

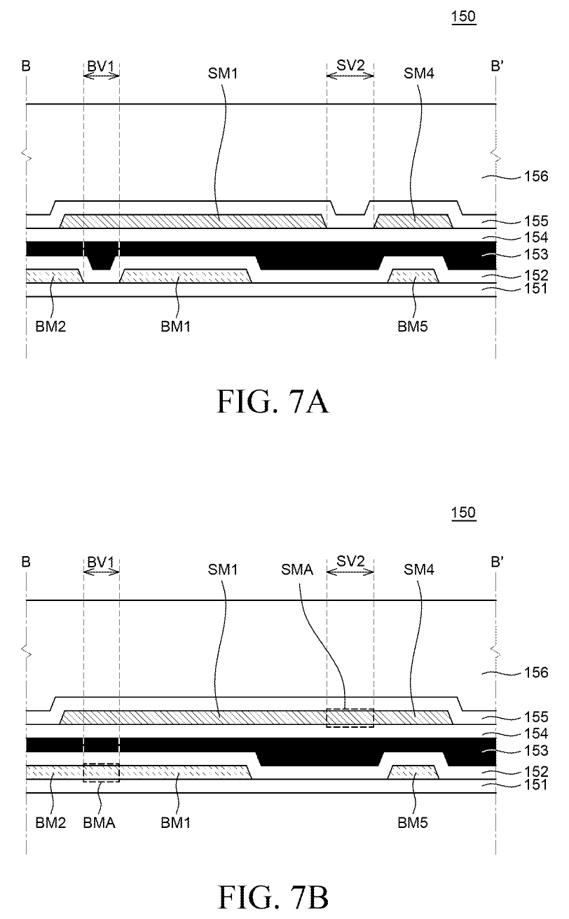

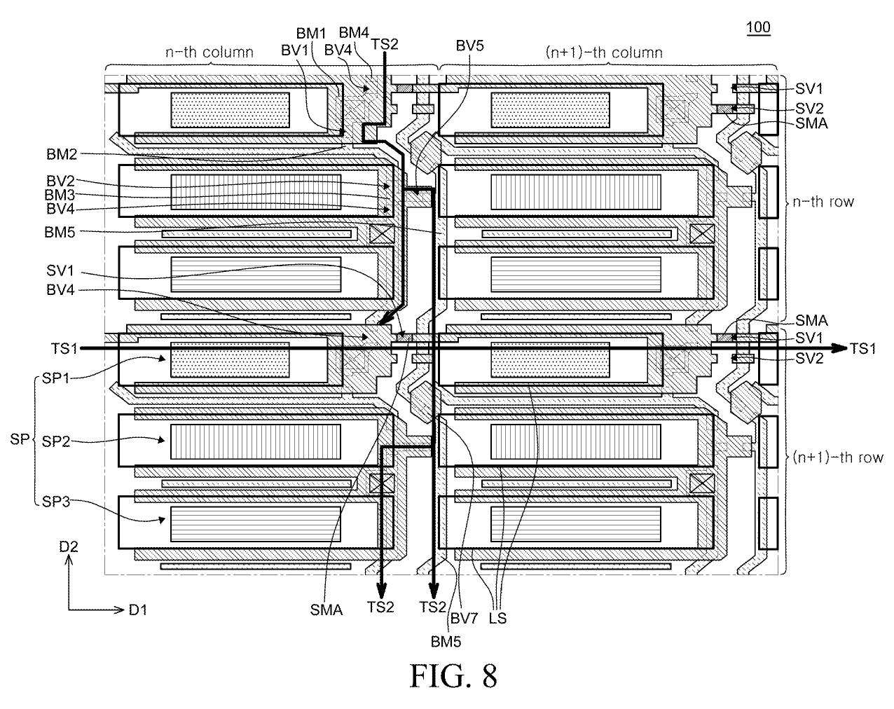

FIG. 4 is an enlarged plan view of a display device according to an exemplary embodiment of the present disclosure. FIG. 5 is a cross-sectional view taken along the line A-Aʹ of FIG. 4. FIG. 6 is an enlarged plan view of an area X of FIG. 4. FIGS. 7A and 7B are cross-sectional views taken along the line B-Bʹ of FIG. 6. FIG. 8 is an enlarged plan view of a display device according to an exemplary embodiment of the present disclosure. For convenience of description, in FIGS. 7A and 7B, only the configuration of the touch unit 150 is illustrated.

Referring to FIG. 4, the display panel PN includes a plurality of sub-pixels SP. The plurality of sub-pixels SP may include a first sub-pixel SP1, a second sub-pixel SP2, and a third sub-pixel SP3. For example, each of the first sub-pixel SP1, the second sub-pixel SP2, and the third sub-pixel SP3 may be a red sub-pixel, a green sub-pixel, and a blue sub-pixel.

The plurality of first sub-pixels SP1 may be disposed in a plurality of rows, the plurality of second sub-pixels SP2 may be disposed in a row adjacent to the plurality of first sub-pixels SP1, and the plurality of third sub-pixels SP3 may be disposed between the plurality of first sub-pixels SP1 and the plurality of second sub-pixels SP2. The first sub-pixel SP1, the second sub-pixel SP2, and the third sub-pixel SP3 may be alternately disposed in the same column.

Referring to FIG. 5, the substrate 110 is a support member for supporting other components of the display device 100 and may be formed of an insulating material. For example, the substrate 110 may be made of glass, resin, or the like.

The substrate 110 may be formed of one or more layers. For example, the substrate 110 may have a double-layer structure including a first substrate 110a and a second substrate 110b on the first substrate 110a. For example, the first substrate 110a and the second substrate 110b may be formed of polyimide (PI). Further, although not illustrated in the drawings, an insulating layer may be further disposed between the first substrate 110a and the second substrate 110b.

An insulating layer group IL is disposed on the substrate 110. The insulating layer group IL may include at least one inorganic insulating layer. For example, the insulating layer group IL may include a multi-buffer layer 111, an active buffer layer 112, a gate insulating layer 113, a first interlayer insulating layer 114, and a second interlayer insulating layer 115.

First, the multi-buffer layer 111 is disposed on the substrate 110. The multi-buffer layer 111 may reduce penetration of moisture or impurities through the substrate 110. For example, the multi-buffer layer 111 may be configured by a single layer or a double layer of an insulating material such as silicon nitride (SiNx), silicon oxide (SiOx), and silicon oxynitride (SiON), but is not limited thereto.

The light shielding layer BSM is disposed on the multi-buffer layer 111. The light shielding layer BSM blocks light incident onto the active layer ACT of the transistor TR below the substrate 110 to minimize a leakage current of the plurality of transistors TR. Further, the light shielding layer BSM may minimize damage to the plurality of transistors TR due to charges trapped in the substrate 110. The light shielding layer BSM is connected to the source electrode SE or the drain electrode DE of the transistor TR to minimize an influence on the threshold voltage of the transistor TR. The light shielding layer BSM may be formed of a single layer or a multi-layer formed of any one or more of molybdenum (Mo), copper (Cu), titanium (Ti), aluminum (Al), chrome (Cr), gold (Au), nickel (Ni), and neodymium (Nd) and an alloy thereof, but is not limited thereto.

The active buffer layer 112 is disposed on the light shielding layer BSM. The active buffer layer 112 may protect the transistor TR from impurities such as alkali ions discharged from the substrate 110. In addition, the active buffer layer 112 may improve adhesion between layers formed on the active buffer layer 112 and the substrate 110. For example, the active buffer layer 112 may be configured by a single layer or a double layer of an insulating material, such as silicon nitride (SiNx), silicon oxide (SiOx), and silicon oxynitride (SiON), but is not limited thereto.

The transistor TR is disposed on the active buffer layer 112. The transistor TR includes an active layer ACT, a gate electrode GE, a source electrode SE, and a drain electrode DE.

First, the active layer ACT is disposed on the active buffer layer 112. The active layer ACT may be formed of a semiconductor material such as an oxide semiconductor, amorphous silicon, or polysilicon, but is not limited thereto.

The gate insulating layer 113 is disposed on the active layer ACT. The gate insulating layer 113 is an insulating layer which insulates the active layer ACT from the gate electrode GE and may be configured by a single layer or a double layer of silicon oxide (SiOx) and/or silicon nitride (SiNx), but is not limited thereto.

The gate electrode GE is disposed on the gate insulating layer 113. The gate electrode GE may be a single layer or multiple layers formed of a conductive material, for example, any one or more of molybdenum (Mo), aluminum (Al), chromium (Cr), gold (Au), titanium (Ti), nickel (Ni), neodymium (Nd), and copper (Cu) and an alloy thereof, but is not limited thereto.

The first interlayer insulating layer 114 is disposed on the gate electrode GE, and the second interlayer insulating layer 115 is disposed on the first interlayer insulating layer 114. The first interlayer insulating layer 114 and the second interlayer insulating layer 115 are insulating layers which protect components therebelow and may be configured by a single layer or a double layer of silicon oxide (SiOx) and/or silicon nitride (SiNx), but are not limited thereto.

The source electrode SE and the drain electrode DE are disposed on the second interlayer insulating layer 115. The source electrode SE and the drain electrode DE may be electrically connected to the active layer ACT through contact holes formed in the second interlayer insulating layer 115, the first interlayer insulating layer 114, and the gate insulating layer 113. The source electrode SE and the drain electrode DE may be configured as a single layer or multilayer structure of a conductive material, such as copper (Cu), aluminum (Al), molybdenum (Mo), nickel (Ni), titanium (Ti), gold (Au), chrome (Cr), and/or an alloy thereof, but are not limited thereto.

The capacitor Cst is disposed on the gate insulating layer 113. The capacitor Cst may include a first capacitor electrode C1 and a second capacitor electrode C2. The first capacitor electrode C1 may be disposed on the gate insulating layer 113, and the second capacitor electrode C2 may be disposed on the first interlayer insulating layer 114. The first capacitor electrode C1 and the second capacitor electrode C2 may overlap each other with the first interlayer insulating layer 114 interposed therebetween. For example, the first capacitor electrode C1 and the second capacitor electrode C2 may be a single layer or multiple layers formed of any one or more of molybdenum (Mo), aluminum (Al), chromium (Cr), gold (Au), titanium (Ti), nickel (Ni), neodymium (Nd), and copper (Cu) and an alloy thereof, but are not limited thereto.

Meanwhile, various conductive layers may be further disposed on the substrate 110. Various conductive layers may constitute any one of a plurality of wiring lines, a plurality of transistors TR, and a plurality of capacitors Cst. For example, the first source-drain conductive layer SDL1 and the second source-drain conductive layer SDL2 may be disposed on the second interlayer insulating layer 115. The first source-drain conductive layer SDL1 may be connected to the first capacitor electrode C1, and the second source-drain conductive layer SDL2 may be connected to the second capacitor electrode C2. Each of the first source-drain conductive layer SDL1 and the second source-drain conductive layer SDL2 may function as an electrode connecting the first capacitor electrode C1 and the second capacitor electrode C2 to another configuration of the sub-pixel SP.

A planarization layer 116 is disposed on the transistor TR. The planarization layer 116 is an insulating layer that planarizes an upper portion of the substrate 110. The planarization layer 116 may be formed of an organic material, and for example, may be configured by a single layer or a double layer of an organic material such as polyimide or photo acryl, but is not limited thereto.

The light-emitting element 120 is disposed on the planarization layer 116. The light-emitting element 120 may be an organic light-emitting diode (OLED). The light-emitting element 120 includes an anode 121, a light-emitting layer 122, and a cathode 123.

The anode 121 is disposed on the planarization layer 116. The anode 121 may be connected to the drain electrode DE of the transistor TR. The anode 121 may be formed of a conductive material having a high work function to supply holes to the light emitting layer 122. For example, the anode 121 may be formed of a transparent conductive material such as indium tin oxide (ITO) or indium zinc oxide (IZO), but is not limited thereto.

Meanwhile, the display device 100 may be implemented as a top emission or bottom emission type. In the case of the top emission type, a reflective layer for reflecting light emitted from the light emitting layer 122 toward the cathode 123 may be disposed below the anode 121. For example, the reflective layer may include a material having excellent reflectivity, such as aluminum (Al) or silver (Ag), but is not limited thereto. Conversely, in the case of the bottom emission type, the anode 121 may be made of only a transparent conductive material. Hereinafter, the description will be made on the assumption that the display device 100 according to the exemplary embodiment of the present disclosure is a top emission type.

The bank 117 is disposed on the anode 121 and the planarization layer 116. The bank 117 may cover an edge of the anode 121. The bank 117 divides the plurality of sub-pixels SP and may prevent color mixture between the plurality of sub-pixels SP. The bank 117 may be an organic insulating material. For example, the bank 117 may be formed of any one of polyimide, acryl, and benzocyclobutene (BCB)-based resin, but is not limited thereto.

The spacer 130 is disposed on the bank 117. It is possible to prevent damage to the light-emitting element 120 that may occur when a fine metal mask (FMM) used to form the light-emitting layer 122 of the light-emitting element 120 directly contacts the bank 117 or the anode 121. The spacer 130 may be formed of the same material as the bank 117 or formed of an insulating material different from the bank 117, but is not limited thereto. Further, the spacer 130 and the bank 117 may be integrally formed at one time. As the spacer 130 is disposed on the bank 117, the cathode 123 may be disposed to cover the spacer 130 and the bank 117.

The light emitting layer 122 is disposed on the anode 121 and the bank 117. The light emitting layer 122 may be an organic layer for emitting light of a specific color. The light emitting layer 122 may further include various layers such as a hole transport layer, a hole injection layer, a hole blocking layer, an electron injection layer, an electron blocking layer, and an electron transport layer. The light emitting layer 122 may be separately formed for each sub-pixel SP to emit different color of light for each sub-pixel SP. For example, the light emitting layer 122 for red (Red), the light emitting layer 122 for green (Green), and the light emitting layer 122 for blue (Blue) may be separately formed in each sub-pixel SP. In contrast, the light-emitting layers 122 which emit white light are commonly formed in the plurality of sub-pixels SP, and a light conversion member which converts white light into light of various colors may be separately provided, and the exemplary embodiments of the present disclosure are not limited thereto.

The cathode 123 is disposed on the light emitting layer 122. The cathode 123 may be formed as one layer over the entire surface of the substrate 110. That is, the cathode 123 may be a common layer commonly formed in the plurality of sub-pixels SP. Since the cathode 123 supplies electrons to the light emitting layer 122, the cathode 123 may be formed of a conductive material having a low work function. The cathode 123 may be formed of, for example, a transparent conductive material such as indium tin oxide (ITO) or indium zinc oxide (IZO), or a metal alloy such as MgAg or an ytterbium (Yb) alloy, and may further include a metal doping layer, but is not limited thereto.

The protection layer 118 is disposed on the cathode 123. The protection layer 118 may protect the light-emitting element 120 so that foreign matter or moisture does not penetrate into the light-emitting element 120. For example, the protection layer 118 may be formed of an inorganic material such as aluminum oxide (Al₂O₃) or silicon nitride (SiNx).

The encapsulation layer 140 is disposed on the protection layer 118. The encapsulation layer 140 may protect the light-emitting element 120 from moisture permeating from the outside of the display device 100. The encapsulation layer 140 includes a first inorganic encapsulation layer 141, an organic encapsulation layer 142, and a second inorganic encapsulation layer 143.

The first inorganic encapsulation layer 141 is disposed on the protection layer 118, and the second inorganic encapsulation layer 143 is disposed on the first inorganic encapsulation layer 141. The first inorganic encapsulation layer 141 and the second inorganic encapsulation layer 143 may serve to block the penetration of moisture or oxygen. The first inorganic encapsulation layer 141 and the second inorganic encapsulation layer 143 may be formed of an inorganic material, for example, an inorganic material such as silicon nitride (SiNx), silicon oxide (SiOx), or aluminum oxide (AlOx), but are not limited thereto.

The organic encapsulation layer 142 is disposed between the first inorganic encapsulation layer 141 and the second inorganic encapsulation layer 143. The organic encapsulation layer 142 may be formed to have a greater thickness than each of the first inorganic encapsulation layer 141 and the second inorganic encapsulation layer 143 to adsorb and block particles that may be generated during the manufacturing process of the display device 100. The organic encapsulation layer 142 may fill cracks that may occur in the first inorganic encapsulation layer 141 and the second inorganic encapsulation layer 143, and cover foreign substances on the first inorganic encapsulation layer 141 to planarize the upper portion. The organic encapsulation layer 142 may be formed of an organic material, for example, an epoxy-based or acryl-based polymer, but is not limited thereto.

The touch unit 150 is disposed on the encapsulation layer 140. The touch unit 150 may sense an external touch input using a user’s finger or a touch pen. The touch unit 150 includes a touch buffer layer 151, a first touch insulating layer 152, a black matrix 153, a second touch insulating layer 154, a third touch insulating layer 155, a touch protection layer 156, a touch electrode TE composed of a bridge metal BM and a sensor metal SM, and a lens LS.

First, the touch buffer layer 151 is disposed on the encapsulation layer 140. The touch buffer layer 151 is an insulating layer for protecting surrounding components such as the encapsulation layer 140 and the light-emitting element 120 during the process of forming the touch unit 150. The touch buffer layer 151 may minimize the permeation of moisture from the outside, a material used in the manufacturing process of the touch unit 150, and the like into the light-emitting element 120. For example, the touch buffer layer 151 may be formed of an insulating material such as silicon oxide (SiOx) or silicon nitride (SiNx), but is not limited thereto.

A plurality of bridge metals BM are disposed on the touch buffer layer 151. The plurality of bridge metals BM may be disposed on the encapsulation layer 140. The plurality of bridge metals BM are metals constituting the touch electrode TE and may be disposed between the plurality of sub-pixels SP. For example, the bridge metal BM may constitute the touch electrode TE together with the sensor metal SM, or may constitute the bridge electrode at an intersection between the first touch electrode TE1 and the second touch electrode TE2. For example, any one of the first touch electrode TE1 and the second touch electrode TE2 is configured by a bridge metal BM, that is, a bridge electrode, in the crossing area of the touch electrode TE, such that the first touch electrode TE1 and the second touch electrode TE2 may be separated. For example, the bridge metal BM may be formed of a metal material such as copper (Cu), aluminum (Al), titanium (Ti), chromium (Cr), nickel (Ni) or a stacked structure of metal materials such as titanium/aluminum/titanium (Ti/Al/Ti), but is not limited thereto.

The first touch insulating layer 152 is disposed on the plurality of bridge metals BM. The first touch insulating layer 152 is an insulating layer which protects the bridge metal BM and insulates the bridge metal BM from the sensor metal SM. For example, the first touch insulating layer 152 may be formed of an insulating material such as silicon oxide (SiOx) or silicon nitride (SiNx), but is not limited thereto.

The black matrix 153 is disposed on the first touch insulating layer 152. The black matrix 153 may be disposed on the plurality of bridge metals BM and include an opening overlapping the plurality of light-emitting elements 120 or the plurality of sub-pixels SP, and light emitted from the light-emitting elements 120 may be directed to the outside of the display device 100. The black matrix 153 may shield light of each of the plurality of sub-pixels SP so as not to be mixed with each other. In addition, the black matrix 153 absorbs light incident from the outside to the display device 100, thereby minimizing a decrease in visibility due to the reflection of external light by the configuration inside the display device 100. For example, the black matrix 153 includes a black component and may be made of an opaque resin including a pigment, but is not limited thereto.

The second touch insulating layer 154 is disposed on the black matrix 153. The second touch insulating layer 154 may planarize an upper portion of the black matrix 153. For example, the second touch insulating layer 154 may be configured by a single layer or a double layer of an organic material, such as polyimide or photo acryl, but is not limited thereto.

A plurality of sensor metals SM are disposed on the second touch insulating layer 154. The plurality of sensor metals SM may be disposed on the black matrix 153. The plurality of sensor metals SM is metals constituting the touch electrode TE and may be disposed between the plurality of sub-pixels SP. For example, the sensor metal SM may constitute the touch electrode TE together with the bridge metal BM. For example, the sensor metal SM may be formed of a metal material such as copper (Cu), aluminum (Al), titanium (Ti), chromium (Cr), and nickel (Ni) or a stacked structure of metal materials such as titanium/aluminum/titanium (Ti/Al/Ti), but is not limited thereto.

The third touch insulating layer 155 is disposed on the plurality of sensor metals SM. The third touch insulating layer 155 may protect the bridge metal BM and the sensor metal SM from external moisture or the like. For example, the third touch insulating layer 155 may be formed of an insulating material such as silicon oxide (SiOx) or silicon nitride (SiNx), but is not limited thereto.

The lens LS is disposed on the third touch insulating layer 155 in each of the plurality of sub-pixels SP. The lens LS may overlap each of the plurality of sub-pixels SP. The lens LS may be disposed to overlap the openings of the light-emitting element 120 and the black matrix 153 to control a viewing angle of light from the light-emitting element 120. The lens LS is a half-cylindrical lens, and may have a rectangular cross section in the length direction of the lens LS and a semicircular cross section in the width direction. Accordingly, the lens LS limits the viewing angle in the width direction and does not limit the viewing angle in the length direction of the lens LS.

In the display device 100 according to the exemplary embodiment of the present disclosure, the longitudinal direction of the lens LS is the same as the first direction D1, and the width direction of the lens LS is aligned with the second direction D2. Therefore, a viewing angle in the left and right directions, which is a viewing angle in the first direction D1, is not limited, and a viewing angle in the vertical direction, which is a viewing angle in the second direction D2, may be limited within a predetermined range. Accordingly, the lens LS may protect information by limiting the viewing angle so that the image is viewed smoothly only within a certain range of viewing angles in the vertical direction from the front of the display panel PN.

The touch protection layer 156 is disposed on the lens LS. The touch protection layer 156 may be disposed on the third touch insulating layer 155. The touch protection layer 156 may protect the plurality of touch electrodes TE and the lens LS from external moisture or impact. For example, the touch protection layer 156 may be made of an organic material such as an epoxy-based or acryl-based polymer, but is not limited thereto.

Referring to FIG. 4, the sensor metal SM includes a first sensor metal SM1, a second sensor metal SM2, a third sensor metal SM3, and a fourth sensor metal SM4.

The plurality of first sensor metals SM1 surrounds each of the plurality of first sub-pixels SP1. For example, the first sensor metal SM1 may be disposed to surround at least three of four sides of the first sub-pixel SP1. For example, the first sensor metal SM1 may be disposed to surround the upper side, the lower side, and the right side of the first sub-pixel SP1.

The plurality of second sensor metals SM2 surrounds a second sub-pixel and a third sub-pixel which are adjacent to each other among the plurality of second sub-pixels SP2 and the plurality of third sub-pixels SP3 together. In the column direction, the first sensor metal SM1 and the second sensor metal SM2 may be alternately disposed. For example, the second sensor metal SM2 may be disposed to surround at least three sides of the second sub-pixel SP2 and at least three sides of the third sub-pixel SP3. For example, the second sensor metal SM2 may be disposed to surround the upper side and the right side of the second sub-pixel SP2, the lower side of the second sub-pixel SP2 and the upper side of the third sub-pixel SP3, and the right side and lower side of the third sub-pixel SP3.

The third sensor metal SM3 is a metal for covering the bridge variable region BV between the plurality of fifth bridge metals BM5 and the bridge variable region BV between the fifth bridge metal BM5 and the second bridge metal BM2. For example, the third sensor metal SM3 may be disposed in an area between the plurality of first sub-pixels SP1 and in an area between the plurality of second sub-pixels SP2. For example, the third sensor metal SM3 may be disposed to cover one end and the other end of the fifth bridge metal BM5 and an end of the second bridge metal BM2 facing the fifth bridge metal BM5.

The fourth sensor metal SM4 may be disposed in an area between the first sensor metal SM1 and the third sensor metal SM3. The fourth sensor metal SM4 may be disposed in an area between the plurality of first sub-pixels SP1. The fourth sensor metal SM4 is a compensation pattern that minimizes pattern visibility according to the presence or absence of metal in the first sensor variable region SV1 together with the second sensor variable region SV2, and a more detailed description will be provided later.

Next, the bridge metal BM includes a first bridge metal BM1, a second bridge metal BM2, a third bridge metal BM3, a fourth bridge metal BM4, a fifth bridge metal BM5, a sixth bridge metal BM6, and a seventh bridge metal BM7.

The first bridge metal BM1 is a metal connected to the first sensor metal SM1 through contact holes of the second touch insulating layer 154, the black matrix 153, and the first touch insulating layer 152. The first bridge metal BM1 may overlap the first sensor metal SM1. By connecting the first bridge metal BM1 to another bridge metal BM, the first sensor metal SM1 may be connected to the second sensor metal SM2 or another bridge metal BM.

The second bridge metal BM2 is a metal for connecting the first bridge metal BM1, the third bridge metal BM3, and the fifth bridge metal BM5 to each other. The second bridge metal BM2 may be disposed between the plurality of second sub-pixels SP2 and the plurality of third sub-pixels SP3. The second bridge metal BM2 may include a portion extending in a column direction between the first bridge metal BM1 and the third bridge metal BM3 and a portion extending in a row direction between the first sensor metal SM1 and the second sensor metal SM2. One end of the portion extending in the column direction may face the first sensor metal SM1, and the other end may face the third bridge metal BM3. One end of the portion extending in the row direction may be connected to the portion extending in the column direction, and the other end may face the fifth bridge metal BM5 and overlap the third sensor metal SM3.

The third bridge metal BM3 is a metal for connecting the second bridge metal BM2, the fourth bridge metal BM4, and the fifth bridge metal BM5 to each other. The third bridge metal BM3 may face the second bridge metal BM2, the fifth bridge metal BM5, and the first bridge metal BM1, respectively. The third bridge metal BM3 may overlap the second sensor metal SM2 in an area between the plurality of second sub-pixels SP2.

The fourth bridge metal BM4 is a metal for connecting the first bridge metal BM1 and the third bridge metal BM3. Further, the fourth bridge metal BM4 is a metal connected to the second sensor metal SM2 through contact holes of the second touch insulating layer 154, the black matrix 153, and the first touch insulating layer 152. One end of the fourth bridge metal BM4 may overlap the second sensor metal SM2, and the other end thereof may overlap the first sensor metal SM1. By connecting the fourth bridge metal BM4 to another bridge metal BM, the second sensor metal SM2 may be connected to the first sensor metal SM1 or another bridge metal BM.

The plurality of fifth bridge metals BM5 extends in the column direction between the sub-pixels SP. The plurality of fifth bridge metals BM5 may be disposed to be spaced apart from each other with an area in which the third sensor metal SM3 is disposed therebetween.

The sixth bridge metal BM6 is a metal extending in the row direction between the second sub-pixel SP2 and the third sub-pixel SP3, and the seventh bridge metal BM7 is a metal extending in the row direction between the third sub-pixel SP3 and the first sub-pixel SP1. The sixth bridge metal BM6 and the seventh bridge metal BM7 may each have an island shape.

Meanwhile, the plurality of sensor metals SM may be separated from each other with the sensor variable region SV interposed therebetween, and the plurality of bridge metals BM may be separated from each other with the bridge variable region BV interposed therebetween. Further, a metal is selectively formed in each of the sensor variable region SV and the bridge variable region BV to connect some of the sensor metals SM to each other or connect some of the bridge metals BM to each other. Accordingly, the connection structure between the sensor metal SM and the bridge metal BM may be variously configured using the metal of the sensor variable region SV and the bridge variable region BV.

Specifically, referring to FIGS. 4, 6, 7A, and 7B, together, a plurality of sensor variable regions SV are disposed between a plurality of sensor metals SM. The sensor variable region SV is a region in which the additional sensor metal SMA is selectively disposed. The additional sensor metal SMA may be disposed in any one of the plurality of sensor variable regions SV. The sensor variable region SV includes a first sensor variable region SV1 and a second sensor variable region SV2. The additional sensor metal SMA may be disposed only in one of the first sensor variable region SV1 and the second sensor variable region SV2 adjacent to each other.

The first sensor variable region SV1 is disposed between a plurality of first sensor metals SM1. The first sensor variable region SV1 may be a variable region for connecting the first sensor metals SM1 disposed in the same row to each other. The additional sensor metal SMA may be formed on the first sensor metal SM1 in the first sensor variable region SV1, such that the first sensor metals SM1 adjacent to each other in the same row may be connected to each other.

The second sensor variable region SV2 is disposed between the first sensor metal SM1 and the fourth sensor metal SM4. The second sensor variable region SV2 may be a variable region for connecting the first sensor metal SM1 and the fourth sensor metal SM4 to each other. The second sensor variable region SV2 may be disposed adjacent to the first sensor variable region SV1. When the additional sensor metal SMA is disposed in the second sensor variable region SV2, the adjacent first sensor metals SM1 may be separated.

Next, referring to FIGS. 4, 6, 7A, and 7B together, a plurality of bridge variable regions BV are disposed between the plurality of bridge metals BM. The plurality of bridge variable regions BV may overlap the black matrix 153 and the plurality of sensor metals SM. The plurality of bridge variable regions BV are regions in which the additional bridge metal BMA is selectively disposed. The plurality of bridge variable regions BV includes a first bridge variable region BV1, a second bridge variable region BV2, a third bridge variable region BV3, a fourth bridge variable region BV4, a fifth bridge variable region BV5, a sixth bridge variable region BV6, and a seventh bridge variable region BV7. The additional bridge metal BMA may be disposed in any one of the plurality of bridge variable regions BV.

The first bridge variable region BV1 is disposed between the first bridge metal BM1 and the second bridge metal BM2. The additional bridge metal BMA may be formed in the first bridge variable region BV1 to connect the first bridge metal BM1, the second bridge metal BM2 and the first sensor metal SM1 adjacent to each other.

The second bridge variable region BV2 is disposed between the second bridge metal BM2 and the third bridge metal BM3. The additional bridge metal BMA may be formed in the second bridge variable region BV2 to connect the second bridge metal BM2 and the third bridge metal BM3 to each other.

The third bridge variable region BV3 is disposed between the third bridge metal BM3 and the fourth bridge metal BM4. The additional bridge metal BMA may be formed in the third bridge variable region BV3 to connect the third bridge metal BM3, the fourth bridge metal BM4 and the second sensor metal SM2 to each other.

The fourth bridge variable region BV4 is disposed between the first bridge metal BM1 and the fourth bridge metal BM4. The additional bridge metal BMA may be formed in the fourth bridge variable region BV4 to connect the first bridge metal BM1, the fourth bridge metal BM4 and the first sensor metal SM1 to each other.

The fifth bridge variable region BV5 is disposed between the third bridge metal BM3 and the fifth bridge metal BM5. The additional bridge metal BMA may be formed in the fifth bridge variable region BV5 to connect the third bridge metal BM3 and the fifth bridge metal BM5 to each other.

The sixth bridge variable region BV6 is disposed between the second bridge metal BM2 and the fifth bridge metal BM5. The additional bridge metal BMA may be formed in the sixth bridge variable region BV6 to connect the fifth bridge metal BM5 and the second bridge metal BM2 to each other.

The seventh bridge variable region BV7 is disposed between a pair of adjacent fifth bridge metals BM5. The additional bridge metal BMA may be formed in the seventh bridge variable region BV7 to connect a pair of adjacent fifth bridge metals BM5.

Meanwhile, since the sensor variable region SV and the bridge variable region BV are regions in which the metal is selectively disposed, the presence or absence of metal in each of the sensor variable region SV and the bridge variable region BV may vary depending on which part of the touch electrode TE they correspond to. Accordingly, a shape difference of the touch electrode TE may occur due to the plurality of sensor variable regions SV and the plurality of bridge variable regions BV. In this case, the pattern of the touch electrode TE is not constant so that the user may more easily recognize the pattern of the touch electrode TE, and accordingly, the display quality may deteriorate.

Accordingly, in the display device 100 according to the exemplary embodiment of the present disclosure, the sensor variable region SV of the sensor metal SM that may be visually recognized from the outside is configured to a minimum, and most of the variable region is configured as the bridge variable region BV. Therefore, the bridge variable region BV may be covered by the sensor metal SM and the black matrix 153. For example, the first bridge variable region BV1 and the fourth bridge variable region BV4 may overlap the first sensor metal SM1 and the black matrix 153, and the second bridge variable region BV2, the third bridge variable region BV3, and the fifth bridge variable region BV5 may overlap the second sensor metal SM2 and the black matrix 153. Further, the sixth bridge variable region BV6 and the seventh bridge variable region BV7 may overlap the third sensor metal SM3 and the black matrix 153. By shielding all of the bridge variable regions BV in which the additional bridge metal BMA is selectively formed with the black matrix 153 and the sensor metal SM, the difference in the pattern shape of the touch electrode TE according to the presence or absence of the additional bridge metal BMA may not be visually recognized by the user.

Meanwhile, an additional sensor metal SMA is selectively formed in the first sensor variable region SV1, and a difference in the pattern shape of the sensor metal SM according to the presence or absence of the additional sensor metal SMA occurs, such that the pattern of the sensor metal SM may be visually recognized by the user. Therefore, the second sensor variable region SV2 and the fourth sensor metal SM4 may be formed adjacent to the first sensor variable region SV1 and the pattern shape of the sensor metal SM may be compensated similarly as a whole.

The overall shape of a part of the first sensor metal SM1 protruding toward the first sensor variable region SV1 and the first sensor variable region SV1 and the overall shape of the second sensor variable region SV2 and the fourth sensor metal SM4 may be configured to be similar. Further, when the additional sensor metal SMA is not formed in the first sensor variable region SV1, the additional sensor metal SMA may be formed in the adjacent second sensor variable region SV2. On the contrary, when the additional sensor metal SMA is formed in the first sensor variable region SV1, the additional sensor metal SMA may not be formed in the adjacent second sensor variable region SV2. Accordingly, the additional sensor metal SMA is selectively formed in the second sensor variable region SV2 to compensate for a shape difference between an area in which the additional sensor metal SMA is formed in the first sensor variable region SV1 and an area in which the additional sensor metal SMA is not formed in the first sensor variable region SV1.

Next, an additional metal may be selectively formed in the plurality of sensor variable regions SV and the plurality of bridge variable regions BV to form connection structures of various sensor metals SM and the bridge metals BM. An exemplary connection structure is illustrated in FIG. 8.

For example, referring to FIG. 8, the plurality of first sensor metals SM1 in the (n+1)-th row may be electrically connected to each other through the additional sensor metal SMA in the first sensor variable region SV1. Accordingly, the plurality of first sensor metals SM1 in the (n+1)-th row may transmit the first touch signal TS1 in the first direction D1.

As another example, in an area between the sub-pixel SP in an n-th column and the sub-pixel SP in an (n+1)-th column, the second touch signal TS2 may be transmitted in the second direction D2 through the plurality of sensor metals SM and the plurality of bridge metals BM. For example, the second touch signal TS2 may be sequentially transmitted from the fourth bridge metal BM4 at the top of the n-th column to the additional bridge metal BMA of the fourth bridge variable region BV4, the first bridge metal BM1, the additional bridge metal BMA of the first bridge variable region BV1, the second bridge metal BM2, the additional bridge metal BMA of the second bridge variable region BV2, the third bridge metal BM3, the additional bridge metal BMA of the fifth bridge variable region BV5, the fifth bridge metal BM5, and the additional bridge metal BMA of the seventh bridge variable region BV7, and the fifth bridge metal BM5.

In this case, the additional bridge metal BMA is not disposed in the fourth bridge variable region BV4 between the fourth bridge metal BM4 in the n-th row and the first bridge metal BM1 in the (n+1)-th row. Accordingly, the second touch signal TS2 may not be applied to the first sensor metal SM1 and the first bridge metal BM1 in the (n+1)-th row to which the first touch signal TS1 is applied.

As another example, the first sensor metal SM1 disposed in the n-th row and the (n+1)-th column is not connected to the first sensor metal SM1 on the right side, and the additional sensor metal SMA is not disposed in the first sensor variable region SV1. In this case, the additional sensor metal SMA is formed in the second sensor variable region SV2, such that two adjacent first sensor metals SM1 may not be connected to each other, and the shape may be similarly corrected with another region in which the additional sensor metal SMA is disposed in the first sensor variable region SV1.

Accordingly, in the display device 100 according to the exemplary embodiment of the present disclosure, most of the variable regions are configured as a bridge variable region BV between the bridge metals BM, such that the bridge variable region BV may be covered with the black matrix 153 and the sensor metal SM. Therefore, the bridge variable region BV may be shielded by using the black matrix 153 and the sensor metal SM, and the pattern recognition of the touch electrode TE due to the shape difference of the bridge variable region BV may be prevented.

The exemplary embodiments of the present disclosure can also be described as follows:

According to an aspect of the present disclosure, a display device includes a substrate including a plurality of sub-pixels. The display device further includes a light-emitting element disposed in each of the plurality of sub-pixels. The display device further includes an encapsulation layer disposed on the light-emitting element. The display device further includes a touch unit disposed on the encapsulation layer. The touch unit includes a plurality of bridge metals disposed on the encapsulation layer, a black matrix disposed on the plurality of bridge metals and having a plurality of openings overlapping the plurality of sub-pixels, a plurality of sensor metals disposed on the black matrix, a plurality of bridge variable regions disposed between the plurality of bridge metals, and a plurality of sensor variable regions disposed between the plurality of sensor metals. The plurality of bridge variable regions overlap the black matrix and the plurality of sensor metals.

The touch unit may further include a touch buffer layer disposed between the encapsulation layer and the plurality of bridge metals, a first touch insulating layer disposed between the plurality of bridge metals and the black matrix, a second touch insulating layer disposed between the black matrix and the plurality of sensor metals, a third touch insulating layer disposed on the plurality of sensor metals, and a touch protection layer disposed on the third touch insulating layer.

The display device may further include a plurality of lenses which is disposed between the third touch insulating layer and the touch protection layer and overlaps each of the plurality of sub-pixels. Each of the plurality of lenses may be a half-cylindrical lens.

The plurality of lenses may have a rectangular cross section in a length direction and a semicircular cross section in a width direction. Each of the plurality of lenses may be configured to limit a viewing angle in the width direction.

The plurality of sub-pixels may include a plurality of first sub-pixels disposed in a plurality of rows, a plurality of second sub-pixels disposed in a row adjacent to the plurality of first sub-pixels, and a plurality of third sub-pixels disposed between the plurality of first sub-pixels and the plurality of second sub-pixels. The plurality of first sub-pixels, the plurality of second sub-pixels, and the plurality of third sub-pixels may be alternately disposed in the same column.

The plurality of sensor metals may include a first sensor metal which encloses each of the plurality of first sub-pixels, a second sensor metal which encloses both a second sub-pixel and a third sub-pixel which are adjacent to each other among the plurality of second sub-pixels and the plurality of third sub-pixels, a third sensor metal disposed in an area between the plurality of first sub-pixels, and a fourth sensor metal disposed in an area between the plurality of first sub-pixels.

The plurality of sensor variable regions may include a first sensor variable region disposed between the first sensor metal disposed in the same row, and a second sensor variable region disposed between the first sensor metal and the fourth sensor metal. The first sensor variable region and the second sensor variable region may be disposed adjacent to each other.

The display device may further include an additional sensor metal disposed in any one of the plurality of sensor variable regions. The additional sensor metal may be disposed only in one of the first sensor variable region and the second sensor variable region adjacent to each other.

When the additional sensor metal is disposed in the first sensor variable region, the first sensor metals disposed in the same row may be connected to each other by the additional sensor metal. When the additional sensor metal is disposed in the second sensor variable region, the adjacent first sensor metals may be separated.

The plurality of bridge metals may include a first bridge metal which overlaps the first sensor metal and is connected to the first sensor metal, a second bridge metal which is disposed between the plurality of second sub-pixels and the plurality of third sub-pixels, a third bridge metal which overlaps the second sensor metal in an area between the plurality of second sub-pixels, a fourth bridge metal of which one end overlaps the second sensor metal and the other end overlaps the first sensor metal and which is connected to the second sensor metal, a fifth bridge metal which extends in a column direction in an area between the plurality of sub-pixels, a sixth bridge metal which is disposed between the plurality of second sub-pixels and the plurality of third sub-pixels, and a seventh bridge metal which is disposed between the plurality of third sub-pixels and the plurality of first sub-pixels.

The plurality of bridge variable regions may include a first bridge variable region disposed between the first bridge metal and the second bridge metal, a second bridge variable region disposed between the second bridge metal and the third bridge metal, a third bridge variable region disposed between the third bridge metal and the fourth bridge metal, a fourth bridge variable region disposed between the first bridge metal and the fourth bridge metal, a fifth bridge variable region disposed between the third bridge metal and the fifth bridge metal, a sixth bridge variable region disposed between the fifth bridge metal and the second bridge metal, and a seventh bridge variable region disposed between a pair of adjacent fifth bridge metals.

The first bridge variable region and the fourth bridge variable region may overlap the first sensor metal. The second bridge variable region, the third bridge variable region and the fifth bridge variable region may overlap the second sensor metal. The sixth bridge variable region and the seventh bridge variable region may overlap the third sensor metal.

The display device may further include an additional bridge metal disposed in any one of the plurality of bridge variable regions.

When the additional bridge metal is disposed in the first bridge variable region, the first bridge metal, the second bridge metal, and the first sensor metal may be connected to each other. When the additional bridge metal is disposed in the second bridge variable region, the second bridge metal and the third bridge metal may be connected to each other. When the additional bridge metal is disposed in the third bridge variable region, the third bridge metal, the fourth bridge metal, and the second sensor metal may be connected to each other. When the additional bridge metal is disposed in the fourth bridge variable region, the fourth bridge metal, the first bridge metal, and the first sensor metal may be connected to each other.

When the additional bridge metal is disposed in the fifth bridge variable region, the third bridge metal and the fifth bridge metal may be connected to each other. When the additional bridge metal is disposed in the sixth bridge variable region, the fifth bridge metal and the second bridge metal may be connected to each other. When the additional bridge metal is disposed in the seventh bridge variable region, the pair of adjacent fifth bridge metals may be connected to each other.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

1. A display device, comprising:
a substrate including a plurality of sub-pixels;
a light-emitting element disposed in each sub-pixel of the plurality of sub-pixels;
an encapsulation layer disposed on the light-emitting element; and
a touch unit disposed on the encapsulation layer,
wherein the touch unit includes:
a plurality of bridge metals disposed on the encapsulation layer;
a black matrix disposed on the plurality of bridge metals;
a plurality of openings in the black matrix overlapping the plurality of sub-pixels;
a plurality of sensor metals disposed on the black matrix;
a plurality of bridge variable regions disposed between the plurality of bridge metals; and
a plurality of sensor variable regions disposed between the plurality of sensor metals,
wherein the plurality of bridge variable regions overlap the black matrix and the plurality of sensor metals.

2. The display device according to claim 1, wherein the touch unit further includes:
a touch buffer layer disposed between the encapsulation layer and the plurality of bridge metals;
a first touch insulating layer disposed between the plurality of bridge metals and the black matrix;
a second touch insulating layer disposed between the black matrix and the plurality of sensor metals;
a third touch insulating layer disposed on the plurality of sensor metals; and
a touch protection layer disposed on the third touch insulating layer.

3. The display device according to claim 2, further comprising:
a plurality of lenses which is disposed between the third touch insulating layer and the touch protection layer and overlaps each of the plurality of sub-pixels,
wherein each of the plurality of lenses is a half-cylindrical lens.

4. The display device according to claim 3, wherein the plurality of lenses has a rectangular cross section in a length direction and a semicircular cross section in a width direction, and
wherein each of the plurality of lenses is configured to limit a viewing angle in the width direction.

5. The display device according to claim 1, wherein the plurality of sub-pixels includes:
a plurality of first sub-pixels disposed in a plurality of rows;
a plurality of second sub-pixels disposed in a row adjacent to the plurality of first sub-pixels; and
a plurality of third sub-pixels disposed between the plurality of first sub-pixels and the plurality of second sub-pixels, and
wherein the plurality of first sub-pixels, the plurality of second sub-pixels, and the plurality of third sub-pixels are alternately disposed in a same column.

6. The display device according to claim 5, wherein the plurality of sensor metals includes:
a first sensor metal which encloses each of the plurality of first sub-pixels;
a second sensor metal which encloses both a second sub-pixel and a third sub-pixel which are adjacent to each other among the plurality of second sub-pixels and the plurality of third sub-pixels;
a third sensor metal disposed in an area between the plurality of first sub-pixels; and
a fourth sensor metal disposed in an area between the plurality of first sub-pixels.

7. The display device according to claim 6, wherein the plurality of sensor variable regions includes:
a first sensor variable region disposed between the first sensor metals that is disposed in the same row; and
a second sensor variable region disposed between the first sensor metal and the fourth sensor metal, and
wherein the first sensor variable region and the second sensor variable region are disposed adjacent to each other.

8. The display device according to claim 7, further comprising:
an additional sensor metal disposed in any one of the plurality of sensor variable regions,
wherein the additional sensor metal is disposed only in one of the first sensor variable region and the second sensor variable region adjacent to each other.

9. The display device according to claim 8, wherein when the additional sensor metal is disposed in the first sensor variable region, the first sensor metals disposed in a same row are connected to each other by the additional sensor metal, and
wherein when the additional sensor metal is disposed in the second sensor variable region, the adjacent first sensor metals are separated.

10. The display device according to claim 6, wherein the plurality of bridge metals includes:
a first bridge metal which overlaps the first sensor metal and is connected to the first sensor metal;
a second bridge metal which is disposed between the plurality of second sub-pixels and the plurality of third sub-pixels;
a third bridge metal which overlaps the second sensor metal in an area between the plurality of second sub-pixels;
a fourth bridge metal of which one end overlaps the second sensor metal and the other end overlaps the first sensor metal and which is connected to the second sensor metal;
a fifth bridge metal which extends in a column direction in an area between the plurality of sub-pixels;
a sixth bridge metal which is disposed between the plurality of second sub-pixels and the plurality of third sub-pixels; and
a seventh bridge metal which is disposed between the plurality of third sub-pixels and the plurality of first sub-pixels.

11. The display device according to claim 10, wherein the plurality of bridge variable regions includes:
a first bridge variable region disposed between the first bridge metal and the second bridge metal;
a second bridge variable region disposed between the second bridge metal and the third bridge metal;
a third bridge variable region disposed between the third bridge metal and the fourth bridge metal;
a fourth bridge variable region disposed between the first bridge metal and the fourth bridge metal;
a fifth bridge variable region disposed between the third bridge metal and the fifth bridge metal;
a sixth bridge variable region disposed between the fifth bridge metal and the second bridge metal; and
a seventh bridge variable region disposed between a pair of adjacent fifth bridge metals.

12. The display device according to claim 11, wherein the first bridge variable region and the fourth bridge variable region overlap the first sensor metal,
wherein the second bridge variable region, the third bridge variable region and the fifth bridge variable region overlap the second sensor metal, and
wherein the sixth bridge variable region and the seventh bridge variable region overlap the third sensor metal.

13. The display device according to claim 11, further comprising an additional bridge metal disposed in any one of the plurality of bridge variable regions.

14. The display device according to claim 13, wherein when the additional bridge metal is disposed in the first bridge variable region, the first bridge metal, the second bridge metal, and the first sensor metal are connected to each other,
wherein when the additional bridge metal is disposed in the second bridge variable region, the second bridge metal and the third bridge metal are connected to each other,
wherein when the additional bridge metal is disposed in the third bridge variable region, the third bridge metal, the fourth bridge metal, and the second sensor metal are connected to each other, and
wherein when the additional bridge metal is disposed in the fourth bridge variable region, the fourth bridge metal, the first bridge metal, and the first sensor metal are connected to each other.

15. The display device according to claim 13, wherein when the additional bridge metal is disposed in the fifth bridge variable region, the third bridge metal and the fifth bridge metal are connected to each other,
wherein when the additional bridge metal is disposed in the sixth bridge variable region, the fifth bridge metal and the second bridge metal are connected to each other, and
wherein when the additional bridge metal is disposed in the seventh bridge variable region, the pair of adjacent fifth bridge metals are connected to each other.

16. The display device according to claim 6, wherein the first sensor metal is disposed to surround at least three of four sides of the first sub-pixel.

17. The display device according to claim 6, wherein the second sensor metal is disposed to surround at least three sides of the second sub-pixel and at least three sides of the third sub-pixel.

18. The display device according to claim 6, wherein the third sensor metal is further disposed in an area between the plurality of second sub-pixels.

19. The display device according to claim 10, wherein the second bridge metal includes a portion extending in a column direction between the first bridge metal and the third bridge metal and a portion extending in a row direction between the first sensor metal and the second sensor metal.

20. The display device according to claim 10, wherein the fourth bridge metal is a metal for connecting the first bridge metal and the third bridge metal.
